(19) United States
(12) Patent Application Publication
(10) Pub. No.: US 2012/0256193 A1
(43) Pub. Date: Oct. 11, 2012

(54) MONOLITHIC INTEGRATED CAPACITORS FOR HIGH-EFFICIENCY POWER CONVERTERS

(75) Inventors: Francois Hebert, San Mateo, CA (US); Stephen J. Gaul, Melbourne Village, FL (US); Shea Petricek, Dallas, TX (US)

(73) Assignee: INTERSIL AMERICAS INC., Milpitas, CA (US)

(21) Appl. No.: 13/165,396

(22) Filed: Jun. 21, 2011

Related U.S. Application Data
(60) Provisional application No. 61/473,523, filed on Apr. 8, 2011.

(51) Int. Cl. H01L 29/02; H01L 29/06; H01L 21/02; H01L 29/92

(52) U.S. Cl. 257/77; 257/532; 257/506; 257/507; 257/76; 438/381; 257/E29.342; 257/E29.02; 257/E29.002; 257/E21.008

(57) ABSTRACT

A semiconductor structure such as a power converter with an integrated capacitor is provided, and comprises a semiconductor substrate, a high-side output power device over the substrate at a first location, and a low-side output power device over the substrate at a second location adjacent to the first location. A first metal layer is over the high-side output power device and electrically coupled to the high-side output power device, and a second metal layer is over the low-side output power device and electrically coupled to the low-side output power device. A dielectric layer is over a portion of the first metal layer and a portion of the second metal layer, and a top metal layer is over the dielectric layer. The integrated capacitor comprises a first bottom electrode that includes the portion of the first metal layer, a second bottom electrode that includes the portion of the second metal layer, the dielectric layer over the portions of the first and second metal layers, and a top electrode that includes the top metal layer over the dielectric layer.

This application claims the benefit of priority to U.S. Provisional Application No. 61/473,523, filed on Apr. 8, 2011, the disclosure of which is incorporated by reference.

### DRAWINGS

Understanding that the drawings depict only exemplary embodiments and are not therefore to be considered limiting in scope, the exemplary embodiments will be described with additional specificity and detail through the use of the accompanying drawings, in which:

FIG. 1 is a block diagram of a system that includes a power converter with one or more monolithic integrated capacitors;

FIG. 2 is a cross-sectional side view of a semiconductor structure that includes a monolithic integrated capacitor according to one embodiment;

FIG. 3 is a cross-sectional side view of a semiconductor structure that includes a monolithic integrated capacitor according to another embodiment;

FIG. 4 is a cross-sectional side view of a semiconductor structure that includes a monolithic integrated capacitor according to a further embodiment;

FIG. 5 is a cross-sectional side view of a semiconductor structure that includes a monolithic integrated capacitor according to another embodiment;

FIG. 6 is a cross-sectional side view of a semiconductor structure that includes monolithic integrated capacitors according to an alternative embodiment; and

FIGS. 7A and 7B are a plan view and a side view in section of a packaged power converter device according to another embodiment.

In accordance with common practice, the various described features are not drawn to scale but are drawn to emphasize specific features relevant to the exemplary embodiments. Like structures are described and shown in the drawings with like reference numbers.

### DETAILED DESCRIPTION

In the following detailed description, reference is made to the accompanying drawings that form a part hereof, and in which is shown by way of illustration specific illustrative embodiments. It is to be understood that other embodiments may be utilized and that mechanical and electrical changes may be made. The following detailed description is, therefore, not to be taken in a limiting sense.

Semiconductor structures that include monolithic integrated capacitors are disclosed herein. The monolithic integrated capacitors can be implemented in various semiconductor structures that include high side devices and low side devices. For example, the monolithic integrated capacitors can be implemented in high-efficiency power converter devices. In other embodiments, the monolithic integrated capacitors can be implemented in half bridge and full bridge drivers.

In one embodiment, a power converter device comprises a conductive substrate, and a power die having an upper surface and a lower surface. The upper surface includes a monolithic integrated capacitor and the lower surface is mounted to the conductive substrate. The power die includes a voltage-in layer coupled to a drain of a device in the power die, and a ground layer coupled to a source of a device in the power die. A packaging material encapsulates the power die and at least a portion of the conductive substrate.

In another embodiment, a monolithic bypass capacitor can be integrated between a voltage input (Vin) of a lateral diffusion metal oxide semiconductor (LDMOS) drain and ground for a vertical diffusion metal oxide semiconductor (VDMOS) source, on top of a power die. The integration of bypass capacitors with the power die compensates for parasitic inductances by providing increased efficiency through reduction of the switching power losses. The monolithic integrated capacitors provide a further reduction in parasitic inductance between the capacitor electrode and switching elements, and also provide a reduced profile thickness. The integrated capacitors can be implemented with a capacitance value selected to minimize power loss of the power converter.

The present approach is particularly suitable for fabrication of DC-DC synchronous power converters. Additional benefits of the present monolithic approach include a lower cost, as there is no need to assemble a discrete capacitor, and smaller size (particularly thinner). The present monolithic approach becomes even more effective as the frequency of operation of the circuits increases, since parasitic inductance becomes more of an issue at higher frequencies, and as frequencies go up, the amount of bypass/filtering capacitance reduces.

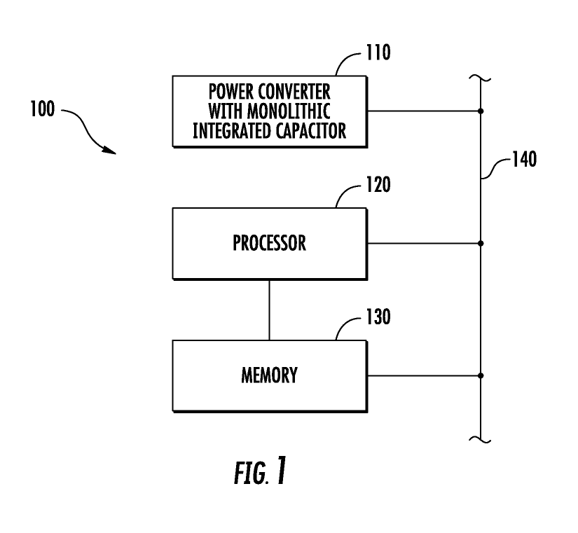

FIG. 1 is a block diagram of a system 100 that includes a power converter 110 including a power die with one or more monolithic integrated capacitors. The power die can include high-side and low-side output power devices that are monolithically integrated in a single die, with the phase (switched output) node at the bottom of the die. The top of the high-side output power device is coupled to a Vin and the top of the low-side output power device is connected to ground. The power converter 110 is electrically coupled to at least one processor 120 and at least one memory device 130. For example, a bus 140 can provide electrical connections between power converter 110, processor 120, and memory device 130. The processor 120 and memory device 130 are also electrically coupled to each other.

The present power converters can be combined in a package with an optional integrated circuit (IC) die to produce a “stand alone” power converter or regulator product. The IC die can be a full featured switching modulator and converter, which generates a pulse-width modulation (PWM) signal, drives the gates of the metal oxide semiconductor field effect transistors (MOSFETs) in the power die, has over current and over voltage protection, etc. The IC die can also be a gate driver, which takes a single PWM signal and drives the gates of the MOSFETs in the power die, a switching regulator circuit, or the like. In addition, the converter/modulator circuit can be implemented using Complementary Metal Oxide Semiconductor (CMOS), BiCMOS, double-diffused MOS (DMOS), or Bipolar CMOS DMOS (BCD) technologies. The IC die can be implemented to drive a single phase power die, or multiple phases including multiple power dies.

The various embodiments described hereafter with reference to the drawings incorporate monolithic integrated capacitors in MOS structures.

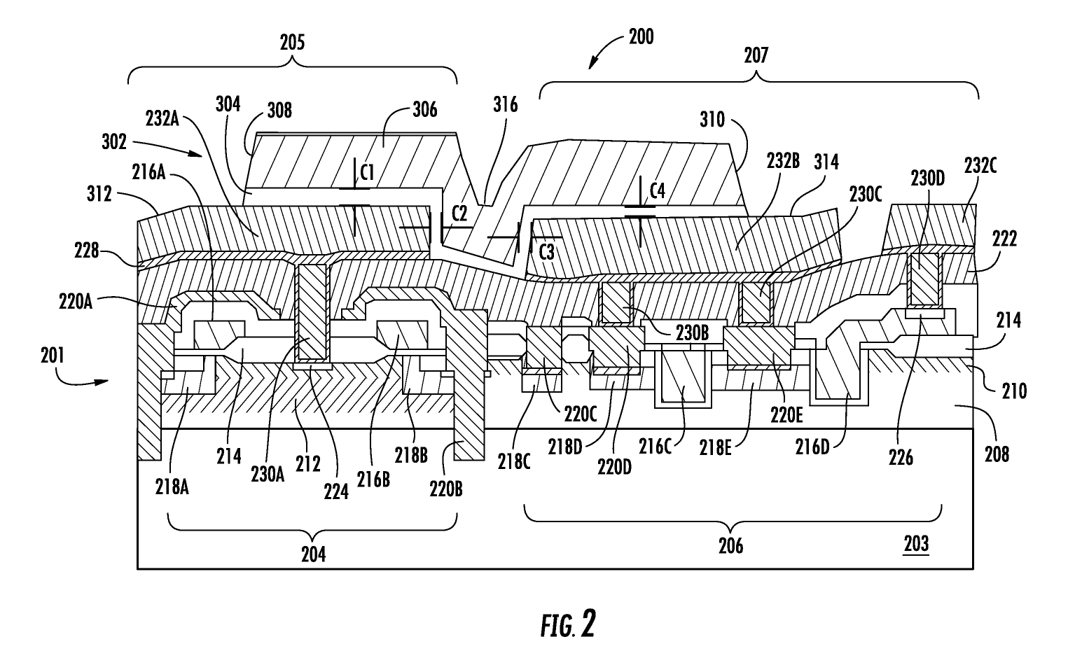

FIG. 2 is a cross-sectional side view of a semiconductor structure 200 that can be implemented in a power converter. The semiconductor structure 200 includes a power die 201 and a monolithic integrated capacitor 302 according to one embodiment. The power die 201 includes a semiconductor substrate 203, such as a wafer or wafer portion of a material including, for example, silicon, gallium arsenide, gallium nitride, silicon carbide, SOI (Silicon on Insulator), sapphire, SOS (Silicon on Sapphire), SOG (Silicon on Glass) and the like.

The power die 201 includes a high-side output power device 204 at a first location 205 over substrate 203, and a low-side output power device 206 over substrate 203 at a second location 207 adjacent to first location 205. In one embodiment, the high-side output power device 204 can include a high performance N-channel LDMOS field effect transistor (FET), and the low-side output power device 206 can include an N-channel VDMOS FET having a trench-gate. Additionally, substrate 203 can provide a switched node (i.e., output node) for power die 201 the bottom of substrate 303. In other embodiments, the output node is not at the bottom of the substrate, but is connected using metal layers.

An epitaxial layer 208 is formed over an upper surface of substrate 203. A blanket N-type drift implant 210 can formed in epitaxial layer 208 by doping with phosphorous, for example. A patterned deep body P-type implant 212 can be formed in epitaxial layer 208 by doping with boron, for example.

A field oxide region 214 is formed over epitaxial layer 208. Individual polysilicon gate portions 216A and 216B are formed over oxide region 214, and polysilicon gate portions 216C and 216D are formed within epitaxial layer 208. The gate portions 216A and 216B form a gate of the high-side device, and gate portions 216C and 216D form portions of a gate for one of the active cells of the low-side device. Body implant regions 218A-218E are also formed in epitaxial layer 208.

Individual conductive structures 220A and 220B, such as a tungsten deep trench fill, are formed over the active region of the high-side device. Similarly, conductive structures 220C-220E, which can also be tungsten deep trench fill, are formed over the active region of the low-side device. Conductive structures 220A and 220B form gate shields to the high-side gate portions 216A and 216B. Conductive structure 220C provides a portion of a floating guard ring, and conductive structures 220D and 220E provide contact portions to the low-side source. An oxide layer 222 is formed over the top of the conductive structures 220A-220E.

A drain 224 is located on the high-side device and a gate contact 226 is located on the low-side gate. A metal barrier layer 228 is formed over oxide layer 222, and individual contact plugs 230A-230D extend from barrier layer 228 through oxide layer 222 to make various electrical contacts with underlying structures. For example, contact plugs 230A and 230D make electrical contact with drain 224 and gate contact 226, respectively.

A plurality of metal layers 232 are formed over barrier layer 228. In one embodiment, a first metal layer 232A is formed over and electrically coupled to the high-side output power device 204. The first metal layer 232A is conductively coupled to drain 224 through contact plug 230A. The first metal layer 232A can also be electrically coupled with a Vin to provide a high-side transistor drain interconnect. A second metal layer 232B is formed over and electrically coupled to the low-side output power device 206. The second metal layer 232B can be electrically coupled with ground to provide a low-side transistor source interconnect. A third metal layer 232C is coupled to gate contact 226 through contact plug 230D.

Further details related to the structure and fabrication of a power die can be found in copending U.S. patent application Ser. No. 12/471,991, filed on May 26, 2009, the disclosure of which is incorporated by reference. An exemplary power die that can be utilized in the present approach is a PowerDie device produced by Intersil.

In an alternative embodiment, the power die can be configured with two N-channel LDMOS devices. The high-side FET would have the drain on top, and the source connected to the substrate (using a conductive trench, for example), while the low-side FET would have the source on top, and the drain connected to the substrate (using a conductive trench, for example). Such a power die is described, for example, in U.S. patent application Ser. No. 12/898,664, filed on Oct. 5, 2010, the disclosure of which is incorporated by reference. The power die can also be configured with two N-channel LDMOS devices that have their source and drain electrodes connected through the top surface, using multiple layers of metal.

As shown in FIG. 2, integrated capacitor 302 has a substantially planar configuration and follows the contours of the upper structures of power die 201. The integrated capacitor 302 includes portions of metal layers 232A and 232B, which form a pair of bottom electrodes of the capacitor structure. The integrated capacitor 302 also includes a dielectric layer 304 over the portions of metal layers 232A and 232B, and a top metal layer 306 over dielectric layer 304 that provides a single common top electrode such as a floating electrode.

The portion of metal layer 232A that forms one bottom electrode is connected to the drain of high side device 204 through contact plug 230A. The portion of metal layer 232B that forms the other bottom electrode is connected to the source of the low side device 206 through contact plug 230B. These two bottom electrodes are at different voltages and not connected to each other. Accordingly, the capacitor can be considered as a single capacitor with two terminals (plugs 230A and 230B) on one side, or as two capacitors (C1+C2; C3+C4) with metal layer 306 (floating top electrode) forming one terminal of each and also forming an ohmic connection therebetween.

During fabrication of integrated capacitor 302, the dielectric layer 304 is formed over metal layers 232A and 232B and a gap 316 therebetween. Thereafter, metal layer 306 is formed over dielectric layer 304. The dielectric layer 304 and metal layer 306 can then be etched according to standard procedures to produce a sidewall 308 adjacent to metal layer 232A and a sidewall 310 adjacent to metal layer 232B. The etched dielectric layer 304 and metal layer 306 expose a surface portion 312 of metal layer 232A and a surface portion 314 of metal layer 232B. The surface portions 312 and 314 provide connection areas for Vin and ground, respectively.

The dielectric layer 304 and metal layer 306 can be formed using various conventional deposition techniques. For example, the electrode layer can be formed using metal deposition techniques, such as sputtering, evaporation, or other techniques including plasma enhanced depositions, and the like. The dielectric layer can be formed using exemplary deposition techniques such as atomic layer deposition (ALD), plasma enhanced depositions, thermal or electron-beam evaporation, and the like.

The dielectric layer 304 can be formed of a single layer of a dielectric material or multiple layers of different dielectric materials. Exemplary dielectric materials include barium strontium titanate (BaSrTiO₃), lead zirconium titanate (Pb(ZRᵢ₋ₓTi)O₃), strontium titanate (SrTiO₃), and tantalum oxide (Ta₂O₅). These materials provide a dielectric constant greater than about 100. Other suitable dielectric materials include hafnium silicate, zirconium silicate, zirconium dioxide, aluminum oxide, silicon dioxide, silicon nitride, silicon oxynitride, and the like. The dielectric layer can also be a multi-layer structure. The dielectric layer may also include a “seed” or “adhesion” layer to ensure a reliable interface between the dielectric material and metal electrodes on the top and bottom.

The metal layer 306 can be formed of various metal materials such as aluminum, copper, Ti, TiN, Ni, tungsten, silicides, and the like.

As shown in FIG. 2, integrated capacitor 302 includes a plurality of capacitance areas C1-C4. The capacitance areas C1 and C2 are located over the high-side output power device 204. The capacitance areas C3 and C4 are located over the low-side output power device 206. The capacitance areas C2 and C3 are also located adjacent to gap 316, which contains a portion of metal layer 306. In addition, the capacitance areas C1 and C2 are in parallel with each other, and capacitance areas C3 and C4 are in parallel with each other. Further, capacitance areas C1 and C2 are in series with capacitance areas C3 and C4 because metal layer 306 is a floating electrode.

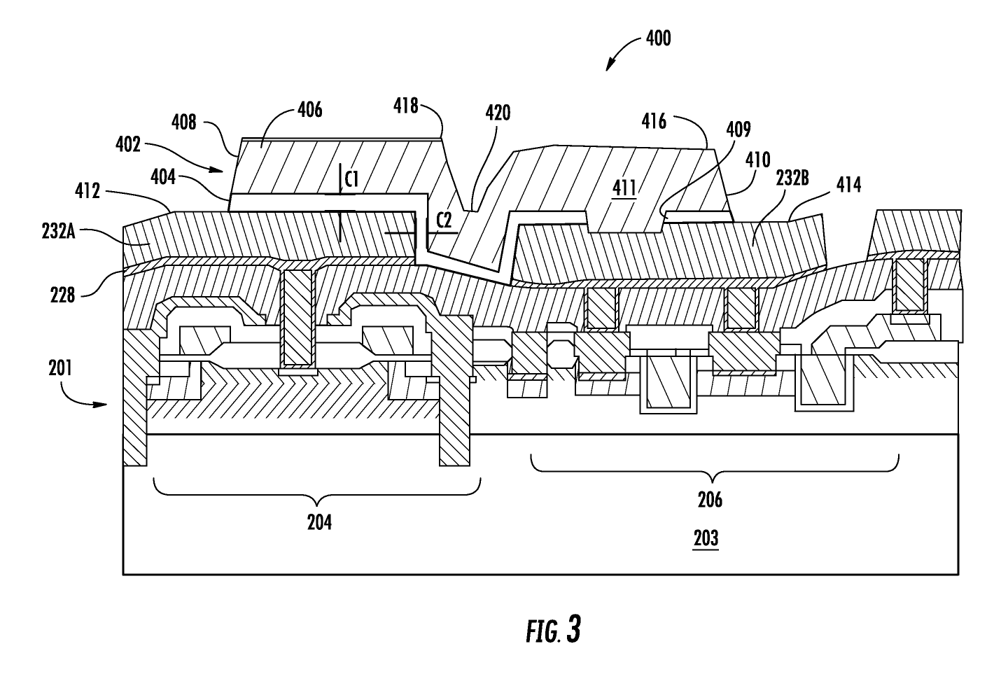

FIG. 3 is a cross-sectional side view of a semiconductor structure 400 that includes a monolithic integrated capacitor 402 according to another embodiment. The semiconductor structure 400, such as a power converter, includes a power die 201 such as described above with respect to FIG. 2. Accordingly, power die 201 includes a semiconductor substrate 203, a high-side output power device 204 over substrate 203, and a low-side output power device 206 over substrate 203. The other structures and layers of power die 201 are the same as described previously, such as a plurality of metal layers 232 formed over a barrier layer 228. A first metal layer 232A can form a high-side transistor drain interconnect and be electrically coupled with Vin. A second metal layer 232B can form a low-side transistor source interconnect and be electrically coupled with ground.

As shown in FIG. 3, integrated capacitor 402 has a substantially planar configuration and follows the contours of the upper structures of power die 201. The integrated capacitor 402 includes a portion of metal layer 232A, which forms a bottom electrode of the capacitor structure. The integrated capacitor 402 also includes a dielectric layer 404 over the portion of metal layer 232A, and a top metal layer 406 over dielectric layer 404 that provides a top electrode. A via 409 is formed in dielectric layer 404 so that metal layer 232B is in conductive contact with metal layer 406. This provides a low-side transistor source extension area 411 in metal layer 406 above via 410.

During fabrication of integrated capacitor 402, the dielectric layer 404 is formed over metal layers 232A and 232B and a gap 420 therebetween. The via 409 is then formed in dielectric layer 404 such as by a standard etching process. Thereafter, metal layer 406 is formed over dielectric layer 404. The dielectric layer 404 and metal layer 406 can then be etched according to standard procedures to produce a sidewall 408 adjacent to metal layer 232A and a sidewall 410 adjacent to metal structure 232B.

The etched dielectric layer 404 and metal layer 406 expose a surface portion 412 of metal layer 232A and surface portion 414 of metal layer 232B. The surface portions 412 and 414 provide connection areas for Vin and ground, respectively. In addition, extension area 411 provides additional connection areas in metal layer 406 at surface portions 416 and 418 for connection to the low-side output power device 206 at ground.

The dielectric layer 404 and metal layer 406 can be formed using various conventional deposition techniques, such as discussed above for FIG. 2. In addition, dielectric layer 404 can be formed of a single layer of a dielectric material or multiple layers of different dielectric materials, such as with those materials described previously. The metal layer 406 can be formed of various metal materials such as described previously.

As shown in FIG. 3, integrated capacitor 402 includes a first capacitance area C1 and a second capacitance area C2 that is in parallel with second capacitance area C1. The first and second capacitance areas C1 and C2 are located over the high-side output power device 204. The capacitance area C2 is also located adjacent to gap 420, which contains a portion of metal layer 406.

In an alternative embodiment, the via 409 can be formed over the high side device 204, and the capacitor (C1+C2) can be formed over the low side device 206. The other structures described in FIG. 3 would be same.

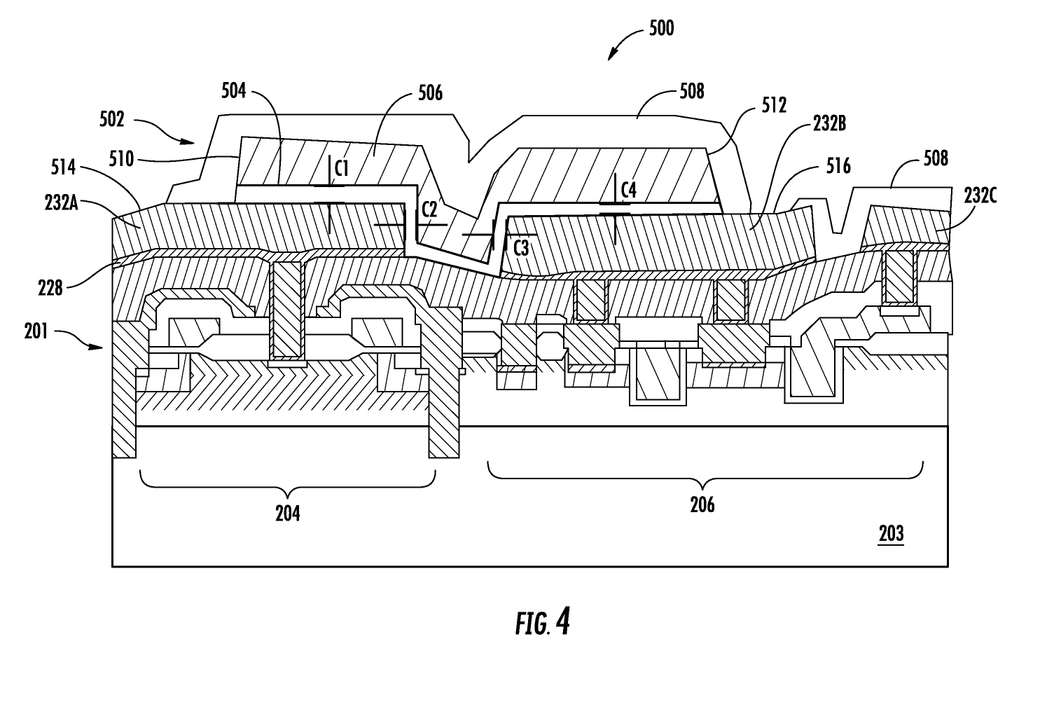

FIG. 4 is a cross-sectional side view of a semiconductor structure 500 that includes a monolithic integrated capacitor 502 according to another embodiment. The semiconductor structure 500 includes similar features as in semiconductor structure 200 shown in FIG. 2, but includes the addition of a top passivation layer 508.

The semiconductor structure 500, such as a power converter, includes a power die 201 such as described above with respect to FIG. 2. Accordingly, power die 201 includes a semiconductor substrate 203, a high-side output power device 204 over substrate 203, and a low-side output power device 206 over substrate 203. The other structures and layers of power die 201 are the same as described previously, such as a plurality of metal layers 232 formed over a barrier layer 228. A first metal layer 232A can form a high-side transistor drain interconnect and be electrically coupled with Vin. A second metal layer 232B can form a low-side transistor source interconnect and be electrically coupled with ground.

As shown in FIG. 4, integrated capacitor 502 has a substantially planar configuration and follows the contours of the upper structures of power die 201. The integrated capacitor 502 includes portions of metal layers 232A and 232B, which form a bottom electrode of the capacitor structure. The integrated capacitor 502 also includes a dielectric layer 504 over the portions of metal layers 232A and 232B, and a top metal layer 506 over dielectric layer 504. The top metal layer 506 provides a single common top electrode such as a floating electrode. In addition, passivation layer 508 is over integrated capacitor 502 and a metal layer 232C.

During fabrication of integrated capacitor 502, the dielectric layer 504 is formed over metal layers 232A and 232B and a gap therebetween. Thereafter, metal layer 506 is formed over dielectric layer 504. The dielectric layer 504 and metal layer 506 can then be etched according to standard procedures to produce a sidewall 510 adjacent to metal layer 232A and a sidewall 512 adjacent to metal layer 232B. The passivation layer 508 is then formed over the top surfaces of integrated capacitor 502 and power die 201. The passivation layer 508 is patterned and etched to expose a surface portion 514 of metal layer 232A and surface portion 516 of metal layer 232B. The surface portions 514 and 516 provide connection areas for Vin and ground, respectively.

The dielectric layer 504, metal layer 506, and passivation layer 508 can be formed using various conventional deposition techniques, such as those discussed above. In addition, dielectric layer 504 can be formed of a single layer of a dielectric material or multiple layers of different dielectric materials, such as with those materials described previously. The metal layer 506 can be formed of various metal materials such as described previously.

The passivation layer 508 can be formed of a single layer of a material or multiple layers of different materials, such as oxides, nitrides, silicon oxynitride, and the like. The passivation layer 508 can also be composed of polyimide or benzocyclobutene (BCB) type films, which are formed by spinning organic materials and curing the materials.

As shown in FIG. 4, integrated capacitor 502 includes a plurality of capacitance areas C1-C4, such as described above for integrated capacitor 302. Thus, capacitance areas C1 and C2 are located over the high-side output power device 204, and capacitance areas C3 and C4 are located over the low-side output power device 206.

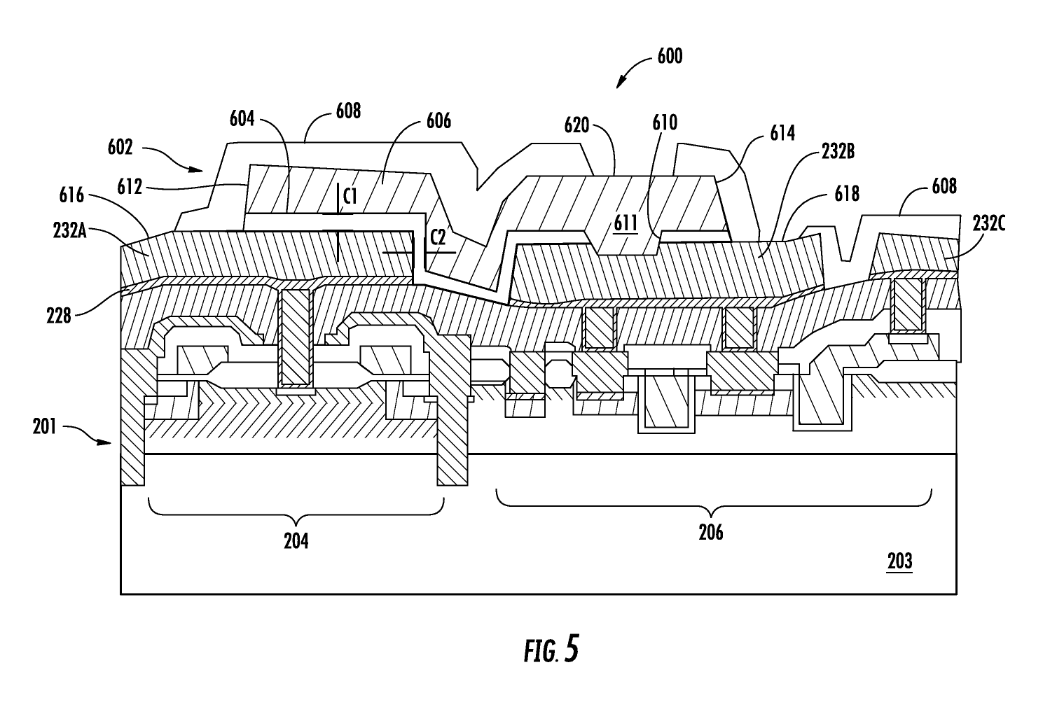

FIG. 5 is a cross-sectional side view of a semiconductor structure 600 that includes a monolithic integrated capacitor 602 according to another embodiment. The semiconductor structure 600 includes similar features as in semiconductor structure 400 shown in FIG. 3, but includes the addition of a top passivation layer 608.

The semiconductor structure 600 includes a power die 201 such as described above with respect to FIG. 2. Accordingly, power die 201 includes a semiconductor substrate 203, a high-side output power device 204 over substrate 203, and a low-side output power device 206 over substrate 203. The other structures and layers of power die 201 are the same as described previously, such as a plurality of metal layers 232 formed over a barrier layer 228. A first metal layer 232A can form a high-side transistor drain interconnect and be electrically coupled with Vin. A second metal layer 232B can form a low-side transistor source interconnect and be electrically coupled with ground.

As shown in FIG. 5, integrated capacitor 602 has a substantially planar configuration and follows the contours of the upper structures of power die 201. The integrated capacitor 602 includes a portion of metal layer 232A, which forms a bottom electrode of the capacitor structure. The integrated capacitor 602 also includes a dielectric layer 604 over the portion of metal layer 232A, and a top metal layer 606 over dielectric layer 604 that provides a top electrode. A via 610 is formed in dielectric layer 604 so that metal layer 232B is in conductive contact with metal layer 606. This provides a low-side transistor source extension area 611 in metal layer 606 above via 610. In addition, passivation layer 608 is over integrated capacitor 602 and a metal layer 232C.

During fabrication of integrated capacitor 602, dielectric layer 604 is formed over metal layers 232A and 232B and a gap therebetween. The via 610 is then formed in dielectric layer 604 such as by a standard etching process. Thereafter, metal layer 606 is formed over dielectric layer 604. The dielectric layer 604 and metal layer 606 can then be etched according to standard procedures to produce a sidewall 612 adjacent to metal layer 232A and a sidewall 614 adjacent to metal layer 232B.

The passivation layer 608 is then formed over the top surfaces of integrated capacitor 602 and power die 201. The passivation layer 608 is etched to form openings that expose a surface portion 616 of metal layer 232A, a surface portion 618 of metal layer 232B, and a surface portion 620 of metal layer 606 over via 610. The surface portions 616 and 618 provide connection areas for Vin and ground, respectively. In addition, surface portion 620 provides an additional connection area for connection to the low-side output power device 206.

The dielectric layer 604, electrode layer 606, and passivation layer 608 can be formed using various conventional deposition techniques, such as those discussed above. In addition, dielectric layer 604 can be formed of a single layer of a dielectric material or multiple layers of different dielectric materials, such as with those materials described previously. The electrode layer 606 can be formed of various metal materials such as described previously. The passivation layer 608 can be formed of a single layer of a material or multiple layers of different materials, such as oxides, nitrides, polyimides, silicon oxynitride, BCB, and the like.

As shown in FIG. 5, integrated capacitor 602 includes capacitance areas C1 and C2, such as described above for integrated capacitor 402. Thus, capacitance areas C1 and C2 are located over the high-side output power device 204.

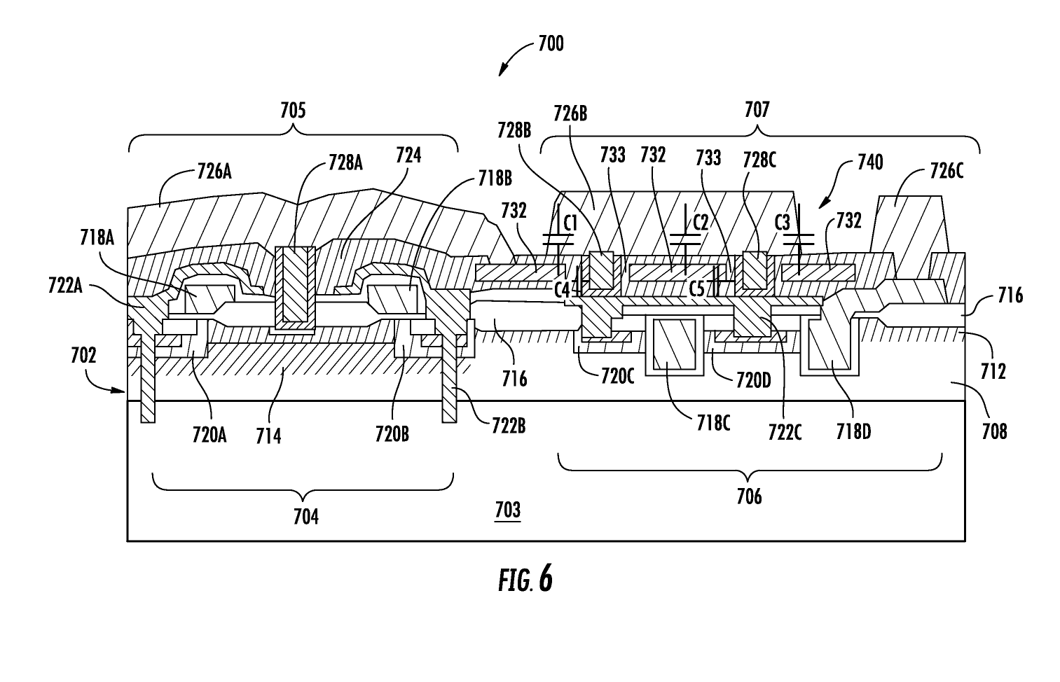

FIG. 6 is a cross-sectional side view of a power converter 700 that includes a monolithic integrated capacitor 740 according to a further embodiment. The power converter 700 includes a power die 702 having a semiconductor substrate 703. The power die 702 includes a high-side output power device 704 at a first location 705 over substrate 703, and a low-side output power device 706 over substrate 703 at a second location 707 laterally adjacent to first location 705. The high-side output power device 704 can be formed using a high performance N-channel LDMOS FET. The low-side output power device 706 can be formed from an N-channel VDMOS FET having a trench-gate, such as a trench double diffused MOS (TDMOS) FET.

In one embodiment, semiconductor substrate 703 can be a silicon substrate heavily doped to an N-type conductivity (N+++). An epitaxial layer 708 over substrate 703 can be formed as an N-type epitaxial layer to a thickness that is a function of the desired breakdown voltage of the low-side output power device 706. Additionally, substrate 703 can provide a switched node to an inductor (not shown).

A blanket N-type drift implant 712 can be formed in epitaxial layer 708 by doping with phosphorous, for example. A patterned deep body P-type implant 714 can be formed in epitaxial layer 708 by doping with boron, for example. A field oxide region 716 is formed over epitaxial layer 708. Individual polysilicon gate portions 718A and 718B are formed over oxide region 716, and polysilicon gate portions 718C and 718D are formed within epitaxial layer 708. Body implant regions 720A-720D such as P-type body implants are also formed in epitaxial layer 708.

Individual conductive structures 722A and 722B, such as a tungsten deep trench fill, are formed over the active region of the high-side output power device 704. A conductive structure 722C, which can also be tungsten deep trench fill, is formed over the active region of the low-side output power device 706.

A dielectric layer 724 is formed over the high-side output power device 704 and the low-side output power device 706, including conductive structures 722A-722C. The dielectric layer 724 can be formed of a single layer of a dielectric material or multiple layers of different dielectric materials, such as those described previously.

A plurality of laterally spaced metal layers 726 are formed on dielectric layer 724. A metal layer 726A is over a portion of the high-side output power device 704. The metal layer 726A can form a conductive drain interconnect and be electrically coupled with Vin. Another metal layer 726B is over a portion of the low-side output power device 706. The metal layer 726B can be a TDMOS source metal interconnect that is electrically coupled with ground. A third metal layer 726C can provide a TDMOS gate contact to the low-side transistor gate.

A contact plug 728A, such as a tungsten plug, connects metal layer 726A with the active region of the high-side output power device 704. Contact plugs 728B and 728C, such as tungsten plugs, connect metal layer 726B with the active region of the low-side output power device 706.

As shown in FIG. 6, a monolithic integrated capacitor 740 is formed by locating a metal layer 732 within dielectric layer 724 under metal structure 726B. The metal layer 732 is formed in dielectric layer 724 prior to metal layers 726A-726C being formed over dielectric layer 724. The metal layer 732 can be formed with a plurality of apertures 733 through which contact plugs 728B and 728C extend. The apertures 733 contain dielectric material from dielectric layer 724. In addition, metal layer 726A is coupled to metal layer 732 to provide a connection between the high-side drain and metal layer 732.

The integrated capacitor 740 includes metal layer 732, which forms a first electrode layer of the capacitor structure, metal layer 726B, which forms a second electrode layer of the capacitor structure, and a portion of dielectric layer 724 that is between metal layer 732 and metal layer 726B. These structures of integrated capacitor 740 produce capacitance areas C1, C2, and C3.

In addition, integrated capacitor 740 includes metal layer 732, which forms the first electrode layer, contact plugs 728B and 728C, which form another electrode layer of the capacitor structure, and the dielectric material of dielectric layer 724 that is contained in apertures 733 between contact plugs 728B, 728C and metal layer 732. These structures of integrated capacitor 740 produce capacitance areas C4 and C5.

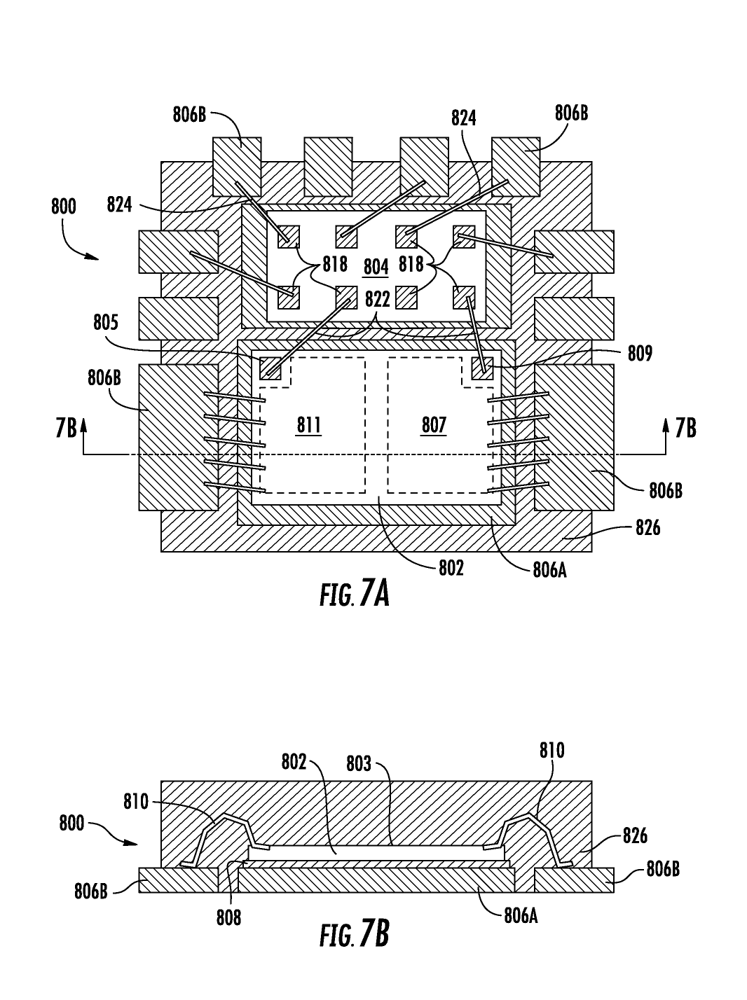

FIGS. 7A and 7B illustrate a packaged power converter 800 according to one exemplary embodiment. The power converter 800 includes a power die 802 and an optional IC die 804 that are mounted to a substrate, such as inner portions 806A of a metal lead frame, with a conductive die attach 808 such as a eutectic solder bond. The power die 802 includes a monolithic integrated capacitor 803, such as any of those described above with respect to FIGS. 2-6. The power die 802 also includes a high-side drain pad 811 (Vin) and a high-side gate pad 805, as well as a low-side source pad 807 (ground) and a low-side gate pad 809.

A plurality of electrical connectors 810 are coupled between an upper surface of power die 802 and outer portions 806B of the lead frame. The electrical connectors can be bond wires, conductive plates, conductive clips, and the like. The electrical connectors 810 provide conductive paths between power die 802 and the lead frame. A plurality of bond pads 818 are located on an upper surface of IC die 804. The bond pads 805 and 809 are electrically connected to respective bond pads 818 by electrical connectors 822, which provide power signals from power die 802 to IC die 804. Other bond pads 818 are electrically connected to various outer portions 806B of the lead frame by electrical connectors 824 to provide outside connections for IC die 804.

A packaging material 826, such as a polymer molding compound, encapsulates the various components of power converter 800, including power die 802 and IC die 804, to seal the components from environmental contamination. Thus, the integrated capacitor of power die 802 does not extend outside of the molded plastic package. Exemplary packaging materials include mold compounds formed of various resins including aromatic or multi-aromatic resins, phenolic resins with filler material such as silica, or other materials that improve electro-magnetic interference (EMI) shielding such as resin materials with a ferrite powder filler.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and the equivalents thereof.

What is claimed is:

1. A semiconductor structure with an integrated capacitor, comprising:
a semiconductor substrate;
a high-side output power device over the semiconductor substrate at a first location;
a low-side output power device over the semiconductor substrate at a second location adjacent to the first location;
a first metal layer over the high-side output power device and electrically coupled to the high-side output power device;
a second metal layer over the low-side output power device and electrically coupled to the low-side output power device;
a dielectric layer over a portion of the first metal layer and a portion of the second metal layer; and
a top metal layer over the dielectric layer;
wherein the integrated capacitor comprises:
a first bottom electrode that includes the portion of the first metal layer;
a second bottom electrode that includes the portion of the second metal layer;
the dielectric layer over the portion of the first metal layer and the portion of the second metal layer; and
a top electrode that includes the top metal layer over the dielectric layer.

2. The semiconductor structure of claim 1, wherein the semiconductor substrate comprises silicon, gallium arsenide, gallium nitride, silicon carbide, silicon-on-insulator, sapphire, silicon-on-sapphire, or silicon-on-glass.

3. The semiconductor structure of claim 1, wherein the dielectric layer comprises a single layer of a dielectric material or multiple sublayers of different dielectric materials.

4. The semiconductor structure of claim 1, wherein the dielectric layer comprises barium strontium titanate, lead zirconium titanate, strontium titanate, tantalum oxide, hafnium silicate, zirconium silicate, zirconium dioxide, aluminum oxide, silicon dioxide, silicon nitride, or silicon oxynitride.

5. The semiconductor structure of claim 1, wherein the integrated capacitor includes a plurality of capacitance areas.

6. The semiconductor structure of claim 1, wherein the integrated capacitor includes a first capacitance area that is in parallel with a second capacitance area.

7. The semiconductor structure of claim 6, wherein the integrated capacitor includes a third capacitance area that is in parallel with a fourth capacitance area.

8. The semiconductor structure of claim 7, wherein the first and second capacitance areas are in series with the third and fourth capacitance areas.

9. The semiconductor structure of claim 1, further comprising a via in the dielectric layer providing conductive contact between the top metal layer and the portion of the second metal layer.

10. The semiconductor structure of claim 9, wherein the integrated capacitor includes a first capacitance area that is in parallel with a second capacitance area, the first and second capacitance areas over the high-side output power device.

11. The semiconductor structure of claim 1, further comprising a via in the dielectric layer providing conductive contact between the top metal layer and the portion of the first metal layer.

12. The semiconductor structure of claim 11, wherein the integrated capacitor includes a first capacitance area that is in parallel with a second capacitance area, the first and second capacitance areas over the low-side output power device.

13. The semiconductor structure of claim 1, further comprising a passivation layer over the top electrode of the integrated capacitor.

14. The semiconductor structure of claim 9, further comprising a passivation layer over the top electrode of the integrated capacitor.

15. The semiconductor structure of claim 14, wherein the passivation layer has an opening that exposes a surface portion of the top electrode.

16. A semiconductor structure, comprising:
a power die comprising:
a semiconductor substrate;
a high-side output power device over the semiconductor substrate at a first location;
a low-side output power device over the semiconductor substrate at a second location laterally adjacent to the first location;
a dielectric layer over the high-side output power device and the low-side output power device;
a first metal layer over the dielectric layer and a portion of the low-side output power device; and
an integrated capacitor in the power die, the integrated capacitor comprising:
a first electrode layer within the dielectric layer;
a second electrode layer including the first metal layer; and
a portion of the dielectric layer that is between the first electrode layer and the second electrode layer.

17. The semiconductor structure of claim 16, wherein the second metal layer is coupled to the low-side output power device through one or more contact plugs that extend through the dielectric layer.

18. The semiconductor structure of claim 16, wherein the one or more contact plugs extend through one or more respective apertures in the first electrode layer, the apertures containing a dielectric material from the dielectric layer.

19. The semiconductor structure of claim 16, wherein the integrated capacitor further comprises:
the first electrode layer within the dielectric layer;
the one or more contact plugs; and
the dielectric material contained in the one or more apertures that is located between the one or more contact plugs and the first electrode layer.

20. The semiconductor structure of claim 16, further comprising a second metal layer over the dielectric layer and a portion of the high-side output power device.

21. The semiconductor structure of claim 20, wherein the second metal layer is coupled to the first electrode layer within the dielectric layer.

22. The semiconductor structure of claim 16, wherein the integrated capacitor includes a plurality of capacitance areas.

23. A packaged power converter device, comprising:
a conductive substrate;
a power die having an upper surface and a lower surface, the upper surface including a monolithic integrated capacitor and the lower surface mounted to the conductive substrate, the power die including a voltage-in layer coupled to a drain of a device in the power die and a ground layer coupled to a source of a device in the power die; and
a packaging material encapsulating the power die and at least a portion of the conductive substrate.

24. The power converter device of claim 23, wherein the substrate comprises a metal lead frame having an inner portion and an outer portion.

25. The power converter device of claim 24, wherein the power die is mounted on the inner portion of the metal lead frame.

26. The power converter device of claim 25, further comprising a first plurality of electrical connectors coupled between an upper surface of the power die and the outer portion of the lead frame, the first plurality of electrical connectors providing a conductive path between the power die and the lead frame.

27. The power converter device of claim 25, further comprising:
an integrated circuit die mounted to the conductive substrate and electrically coupled to the outer portion of the lead frame;
wherein the integrated circuit die is electrically coupled to the power die to receive power signals from the power die.

28. The power converter device of claim 23, wherein the power die further comprises:
a semiconductor substrate;
a high-side output power device over the semiconductor substrate at a first location;
a low-side output power device over the semiconductor substrate at a second location adjacent to the first location;
a first metal layer over the high-side output power device and electrically coupled to the high-side output power device;
a second metal layer over the low-side output power device and electrically coupled to the low-side output power device;
a dielectric layer over a portion of the first metal layer and a portion of the second metal layer; and
a top metal layer over the dielectric layer.

29. The power converter device of claim 28, wherein the integrated capacitor comprises:
a first bottom electrode that includes the portion of the first metal layer;
a second bottom electrode that includes the portion of the second metal layer;
the dielectric layer over the portion of the first metal layer and the portion of the second metal layer; and
a top electrode that includes the top metal layer over the dielectric layer.

30. The power converter device of claim 23, wherein the power die further comprises:
a semiconductor substrate;
a high-side output power device over the semiconductor substrate at a first location;
a low-side output power device over the semiconductor substrate at a second location laterally adjacent to the first location;
a dielectric layer over the high-side output power device and the low-side output power device;
a first metal layer over the dielectric layer and a portion of the low-side output power device; and
a second metal layer over the dielectric layer and a portion of the high-side output power device.

31. The power converter device of claim 30, wherein the integrated capacitor comprises:
a first electrode layer within the dielectric layer;
a second electrode layer including the second metal layer; and
a portion of the dielectric layer that is between the first electrode layer and the second electrode layer.

32. An electronic system comprising:
at least one processor:
at least on memory unit operatively coupled to the processor; and
at least one power converter electrically coupled to the processor and the memory unit, the power converter comprising:
a conductive substrate;
a power die having an upper surface and a lower surface, the upper surface including a monolithic integrated capacitor and the lower surface mounted to the conductive substrate, the power die including a voltage-in layer coupled to a drain of the power die and a ground layer coupled to a source of the power die; and
a packaging material encapsulating the power die and at least a portion of the conductive substrate;

33. The electronic system of claim 32, further comprising:
an integrated circuit die mounted to the conductive substrate;
wherein the integrated circuit die is electrically coupled to the power die to receive power signals from the power die.

34. The electronic system of claim 32, wherein the power die further comprises:
a semiconductor substrate;
a high-side output power device over the semiconductor substrate at a first location;
a low-side output power device over the semiconductor substrate at a second location adjacent to the first location;
a first metal layer over the high-side output power device and electrically coupled to the high-side output power device;
a second metal layer over the low-side output power device and electrically coupled to the low-side output power device;
a dielectric layer over a portion of the first metal layer and a portion of the second metal layer; and
a top metal layer over the dielectric layer;
wherein the integrated capacitor comprises:
a first bottom electrode that includes the portion of the first metal layer;
a second bottom electrode that includes the portion of the second metal layer;
the dielectric layer over the portion of the first metal layer and the portion of the second metal layer; and
a top electrode that includes the top metal layer over the dielectric layer.

35. The electronic system of claim 32, wherein the power die further comprises:
a semiconductor substrate;
a high-side output power device over the semiconductor substrate at a first location;
a low-side output power device over the semiconductor substrate at a second location laterally adjacent to the first location;
a dielectric layer over the high-side output power device and the low-side output power device;
a first metal layer over the dielectric layer and the high-side output power device; and
a second metal layer over the dielectric layer and the low-side output power device;
wherein the integrated capacitor comprises:
a first electrode layer within the dielectric layer;
a second electrode layer including the second metal layer; and
a portion of the dielectric layer that is between the first electrode layer and the second electrode layer.

36. A method of manufacturing a semiconductor device with an integrated capacitor, the method comprising:
providing a semiconductor substrate comprising a high-side device at a first location, and a low-side device at a second location;
forming a first metal layer over the high-side device;
electrically coupling the first metal layer to the high-side device;
forming a second metal layer over the low-side device;
electrically coupling the second metal layer to the low-side device;
forming a dielectric layer over a portion of the first metal layer and a portion of the second metal layer, the portions of the first and second metal layers configured to respectively operate as a first bottom electrode and a second bottom electrode of the integrated capacitor;
forming a top metal layer over the dielectric layer such that the top metal layer is configured to operate as a top electrode of the integrated capacitor.

37. A method of manufacturing a semiconductor device with an integrated capacitor, the method comprising:
providing a semiconductor substrate comprising a high-side device at a first location, and a low-side device at a second location;
forming a dielectric layer over the high-side device and the low-side device;
forming a metal layer over the dielectric layer and a portion of the low-side device; and
forming a first electrode layer within the dielectric layer and over the portion of the low-side device such that the integrated capacitor comprises:
the first electrode layer within the dielectric layer;
a second electrode layer that includes the metal layer; and
a portion of the dielectric layer that is between the first electrode layer and the second electrode layer.
